(19) United States
(12) Patent Application Publication
(10) Pub. No.: US 2023/0288806 A1
(43) Pub. Date: Sep. 14, 2023

(54) PHOTOSENSITIVE POLYMER CAPABLE OF MULTI-STEP DEPROTECTION REACTION, PHOTORESIST COMPOSITION INCLUDING THE PHOTOSENSITIVE POLYMER, AND METHOD OF MANUFACTURING THE INTEGRATED CIRCUIT DEVICE

(71) Applicant: SAMSUNG ELECTRONICS CO., LTD., Suwon-si (KR)

(72) Inventors: Jiyup KIM, Suwon-si (KR); Hyunwoo KIM, Seongnam-si (KR); Sung Hwan PARK, Suwon-si (KR); Juhyeon PARK, Hwaseong-si (KR); Giyoung SONG, Hwaseong-si (KR)

(21) Appl. No.: 18/098,233

(22) Filed: Jan. 18, 2023

(30) Foreign Application Priority Data
Jan. 25, 2022 (KR) 10-2022-0011046

(51) Int. Cl. G03F 7/039; G03F 7/004; C08F 220/28; C08F 216/10; H01L 21/027

(52) U.S. Cl. CPC G03F 7/0397; C08F 216/10; C08F 220/283; G03F 7/0045; H01L 21/0274

(57) ABSTRACT

A photosensitive polymer includes a first repeating unit represented by Formula 1 below:

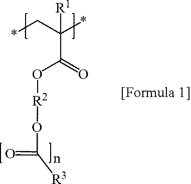

wherein, in Formula 1, R¹ is a hydrogen atom or a methyl group, R² is a substituted or unsubstituted C1 to C30 acid-labile hydrocarbylene group having a tertiary carbon atom, R³ is a C1 to C10 linear or branched alkyl group, a C3 to C30 tertiary alicyclic group, a C6 to C20 aryl group, a C2 to C20 heteroaryl group, a C7 to C20 arylalkyl group, or a C2 to C20 heteroarylalkyl group, and n is 0 or 1. To manufacture an integrated circuit (IC) device, a change in the polarity of the photosensitive polymer is induced by causing a multi-step deprotection reaction of the first repeating unit.

### CROSS-REFERENCE TO RELATED APPLICATION

This application is based on and claims priority under 35 U.S.C. §119 to Korean Patent Application No. 10-2022-0011046, filed on Jan. 25, 2022, in the Korean Intellectual Property Office, the disclosure of which is incorporated by reference herein in its entirety.

### BACKGROUND

### 1. Field

Embodiments relate to a photosensitive polymer, a photoresist composition including the photosensitive polymer, and a method of manufacturing an integrated circuit (IC) device, and more particularly, to a photosensitive polymer capable of a stepwise deprotection reaction, a photoresist composition including the photosensitive polymer, and a method of manufacturing an IC device using the photoresist composition.

### 2. Description of the Related Art

In recent years, due to the development of electronic technology, the downscaling of semiconductor devices has rapidly progressed. Accordingly, a photolithography process that is advantageous for embodying fine patterns has been required.

### SUMMARY

An embodiment is directed to a photosensitive polymer including a first repeating unit represented by Formula 1:

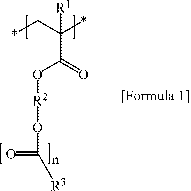

wherein R¹ is a hydrogen atom or a methyl group, R² is a substituted or unsubstituted C1 to C30 acid-labile hydrocarbylene group having a tertiary carbon atom, R³ is a substituted or unsubstituted C1 to C10 linear or branched alkyl group, a substituted or unsubstituted C3 to C30 tertiary alicyclic group, a substituted or unsubstituted C6 to C20 aryl group, a substituted or unsubstituted C2 to C20 heteroaryl group, a substituted or unsubstituted C7 to C20 arylalkyl group, or a substituted or unsubstituted C2 to C20 heteroarylalkyl group, n is 0 or 1, and * is a binding site.

An embodiment is directed to a photoresist composition including a photosensitive polymer including the first repeating unit represented by the Formula 1, a photoacid generator (PAG), and a solvent.

An embodiment is directed to a method of manufacturing an IC device. The method includes forming a photoresist film on an underlayer film using a photoresist composition. The photoresist composition includes a photosensitive polymer including a first repeating unit represented by Formula 1, a PAG, and a solvent. A first area, which is a portion of the photoresist film, is exposed to generate a plurality of acids. A multi-step deprotection reaction of the first repeating unit is caused by using the plurality of acids, and thus, a change in the polarity of the photosensitive polymer is induced. The exposed first area of the photoresist film is removed by using a developer to thereby form a photoresist pattern including a non-exposed area of the photoresist film. The underlayer film is processed by using the photoresist pattern.

### BRIEF DESCRIPTION OF THE DRAWINGS

Features will become apparent to those of skill in the art by describing in detail example embodiments with reference to the attached drawings in which:

FIG. 1 is a flowchart of a method of manufacturing an integrated circuit (IC) device, according to an example embodiment; and

FIGS. 2A to 2E are cross-sectional views of a process sequence of a method of manufacturing an IC device, according to an example embodiment.

### DETAILED DESCRIPTION

A photosensitive polymer according to an example embodiment may include a first repeating unit represented by Formula 1 below:

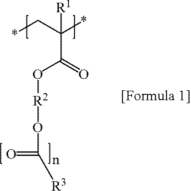

wherein, in Formula 1, R¹ is a hydrogen atom or a methyl group, R² is a substituted or unsubstituted C1 to C30 acid-labile hydrocarbylene group having a tertiary carbon atom, R³ is a substituted or unsubstituted C1 to C10 linear or branched alkyl group, a substituted or unsubstituted C3 to C30 tertiary alicyclic group, a substituted or unsubstituted C6 to C20 aryl group, a substituted or unsubstituted C2 to C20 heteroaryl group, a substituted or unsubstituted C7 to C20 arylalkyl group, or a substituted or unsubstituted C2 to C20 heteroarylalkyl group, n is 0 or 1, and * is a binding site.

As used herein, unless otherwise defined, the term “substituted” may refer to including at least one substitute, for example halogen (e.g., fluorine (F), chlorine (Cl), bromine (Br), or iodine (I)), hydroxy, amino, thiol, carboxy, carboxylate, ester, amide, nitrile, sulfide, disulfide, nitro, C1 to C20 alkyl, C1 to C20 cycloalkyl, C2 to C20 alkenyl, C1 to C20 alkoxy, C2 to C20 alkenoxy, C6 to C30 aryl, C6 to C30 aryloxy, C7 to C30 alkylaryl, or a C7 to C30 alkylaryloxy group.

The photosensitive polymer according to the present example embodiment, which includes the first repeating unit represented by Formula 1, may have a changed solubility to a developer by an action of acid.

In Formula 1, R² may be or include a divalent aliphatic hydrocarbon group or a divalent aromatic hydrocarbon group. The divalent aliphatic hydrocarbon group may have a saturated or unsaturated structure.

In an example embodiment, R² may include a C1 to C10 linear or branched alkylene group. The branched alkylene group may have a structure of, for example, —C(CH₃)(CH₃)CH₂—, —C(CH₃)(CH₂CH₃)CH₂—, —C(CH₃)(CH₂CH₂CH₃)CH₂—, —C(CH₂CH₃)₂CH₂—, —C(CH₃)(CH₃)CH₂CH(CH₃)—, etc.

In an example embodiment, R² may include a divalent cycloaliphatic hydrocarbon group (hereinafter, referred to as an aliphatic hydrocarbylene group). In an example embodiment, the aliphatic hydrocarbylene group may include a substituent having at least one heteroatom functional group including an oxygen atom, a nitrogen atom, a halogen, cyano, thio, silyl, ether, carbonyl, ester, nitro, or amino, or a combination thereof. In an example embodiment, the aliphatic hydrocarbylene group may not include a substituent having the heteroatom functional group.

In an example embodiment, R² may have a structure in which the aliphatic hydrocarbylene group is bonded to an end of a linear or branched aliphatic hydrocarbylene group, or a structure in which the aliphatic hydrocarbylene group is bonded to the middle of the linear or branched aliphatic hydrocarbylene group. The aliphatic hydrocarbylene group may be a monocyclic aliphatic hydrocarbylene group or a polycyclic aliphatic hydrocarbylene group.

In an example embodiment, R² may include a divalent aromatic hydrocarbylene group. The divalent aromatic hydrocarbylene group may include a C6 to C20 aryl group or a C6 to C20 arylalkyl group. In an example embodiment, the divalent aromatic hydrocarbylene group may include a substituent having at least one heteroatom functional group. In an example embodiment, the divalent aromatic hydrocarbylene group may not include a substituent having the heteroatom functional group. The aromatic hydrocarbylene group may be a monocyclic aromatic hydrocarbylene group or a polycyclic aromatic hydrocarbylene group.

In an example embodiment, R² may have any one selected from the structures in the following Group 1. [Group 1]

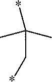 [SMILES: *CC(*)(C)C]

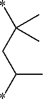 [SMILES: *C(C)CC(*)(C)C]

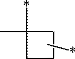

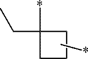

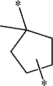

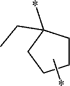

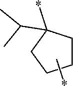

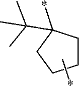

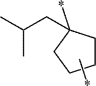

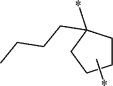

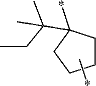

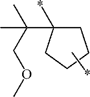

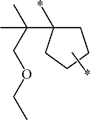

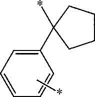

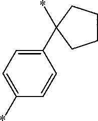 [SMILES: *c1ccc(C2(*)CCCC2)cc1]

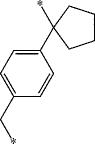 [SMILES: *Cc1ccc(C2(*)CCCC2)cc1]

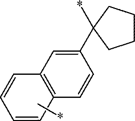

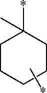

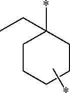

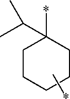

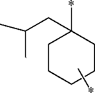

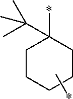

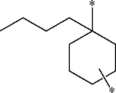

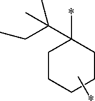

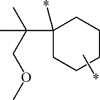

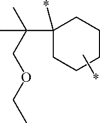

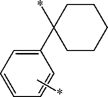

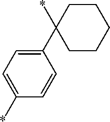 [SMILES: *c1ccc(C2(*)CCCCC2)cc1]

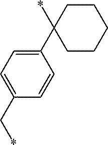 [SMILES: *Cc1ccc(C2(*)CCCCC2)cc1]

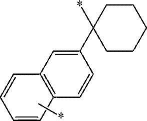

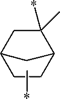

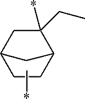

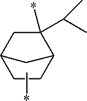

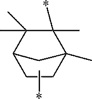

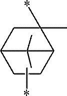

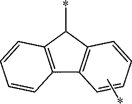

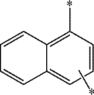

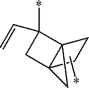

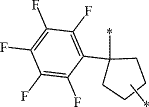

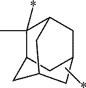

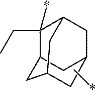

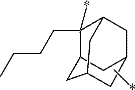

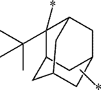

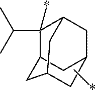

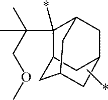

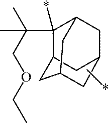

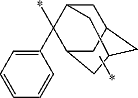

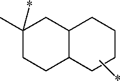

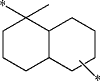

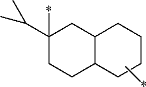

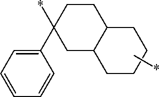

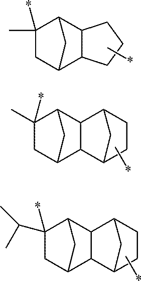

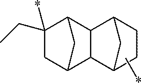

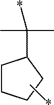

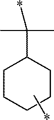

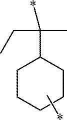

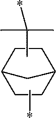

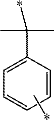

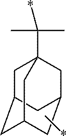

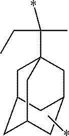

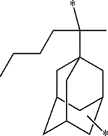

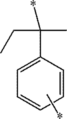

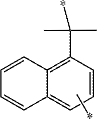

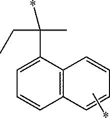

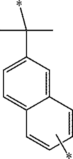

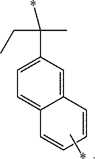

In the above Group 1, “*” denotes a binding site.

In an example embodiment, in Formula 1, R³ may include an unsubstituted C1 to C10 linear or branched alkyl group, or may include a C 1 to C10 linear or branched alkyl group substituted with a fluorine atom.

In an example embodiment, in Formula 1, R³ may include a hydrocarbyl group substituted with at least one heteroatom functional group including an oxygen atom, a nitrogen atom, a halogen, cyano, thio, silyl, ether, carbonyl, ester, nitro, or amino, or a combination thereof. The halogen may be F, Cl, Br, or I.

In an example embodiment, in Formula 1, R³ may have a structure substituted with a first substituent. For example, R³ may include a t-butyl group substituted with the first substituent, or may include a C1 to C30 tertiary alicyclic group substituted with the first substituent. The first substituent may include a C 1 to C10 alkyl group, a C 1 to C10 alkoxy group, a halogen, a C1 to C10 halogenated alkyl group, a hydroxy group, an unsubstituted C6 to C30 aryl group, or a C6 to C30 aryl group in which some of carbon atoms included in the first substituent are substituted with a halogen or a hetero element-containing group. The halogenated alkyl group that may be included in the first substituent may include at least one halogen selected from F, Cl, Br, and I. The heteroatom may be an oxygen (O) atom, a sulfur (S) atom, or a nitrogen (N) atom. For example, the hetero element-containing group may be —O—, —C(═O)—O—, —O—C(═O)—, —C(═O)—, —O—C(═O)—O—, —C(═O)—NH—, —NH—, —S—, —S(═O)₂—, or —S(═O)₂—O—.

In an example embodiment, R³ may have any one selected from the structures in the following Group 2. [Group 2]

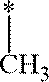 [SMILES: *C]

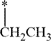 [SMILES: *CC]

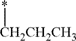

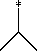 [SMILES: *C(C)C]

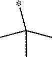 [SMILES: *C(C)(C)C]

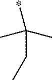 [SMILES: *C(C)(C)CC]

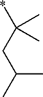 [SMILES: *C(C)(C)CC(C)C]

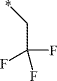 [SMILES: *CC(F)(F)F]

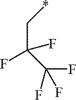 [SMILES: *CC(F)(F)C(F)(F)F]

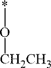 [SMILES: *OCC]

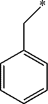 [SMILES: *Cc1ccccc1]

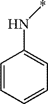 [SMILES: *Nc1ccccc1]

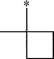 [SMILES: *C1(C)CCC1]

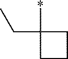 [SMILES: *C1(CC)CCC1]

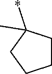 [SMILES: *C1(C)CCCC1]

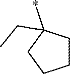 [SMILES: *C1(CC)CCCC1]

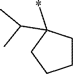 [SMILES: *C1(C(C)C)CCCC1]

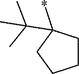 [SMILES: *C1(C(C)(C)C)CCCC1]

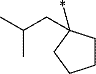 [SMILES: *C1(CC(C)C)CCCC1]

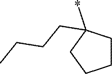 [SMILES: *C1(CCCC)CCCC1]

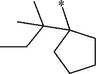 [SMILES: *C1(C(C)(C)CC)CCCC1]

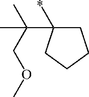 [SMILES: *C1(C(C)(C)COC)CCCC1]

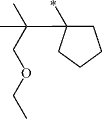 [SMILES: *C1(C(C)(C)COCC)CCCC1]

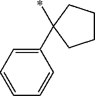 [SMILES: *C1(c2ccccc2)CCCC1]

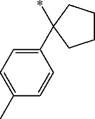 [SMILES: *C1(c2ccc(C)cc2)CCCC1]

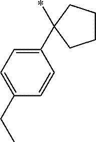 [SMILES: *C1(c2ccc(CC)cc2)CCCC1]

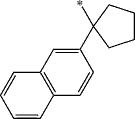 [SMILES: *C1(c2ccc3ccccc3c2)CCCC1]

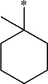 [SMILES: *C1(C)CCCCC1]

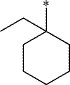 [SMILES: *C1(CC)CCCCC1]

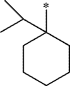 [SMILES: *C1(C(C)C)CCCCC1]

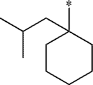 [SMILES: *C1(CC(C)C)CCCCC1]

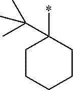 [SMILES: *C1(C(C)(C)C)CCCCC1]

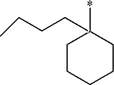

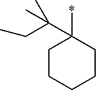 [SMILES: *C1(C(C)(C)CC)CCCCC1]

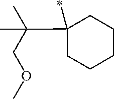 [SMILES: *C1(C(C)(C)COC)CCCCC1]

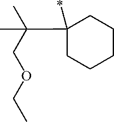 [SMILES: *C1(C(C)(C)COCC)CCCCC1]

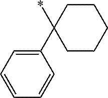 [SMILES: *C1(c2ccccc2)CCCCC1]

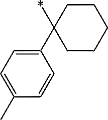 [SMILES: *C1(c2ccc(C)cc2)CCCCC1]

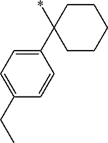 [SMILES: *C1(c2ccc(CC)cc2)CCCCC1]

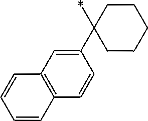 [SMILES: *C1(c2ccc3ccccc3c2)CCCCC1]

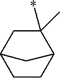 [SMILES: *C1(C)CC2CCC1C2]

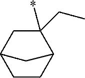 [SMILES: *C1(CC)CC2CCC1C2]

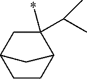 [SMILES: *C1(C(C)C)CC2CCC1C2]

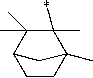

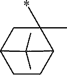 [SMILES: *C1(C)CC2CCC1C2(C)C]

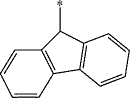 [SMILES: *C1c2ccccc2-c2ccccc21]

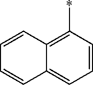 [SMILES: *c1cccc2ccccc12]

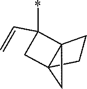 [SMILES: *C1(C=C)CC23CCC12C3]

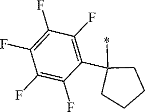 [SMILES: *C1(c2c(F)c(F)c(F)c(F)c2F)CCCC1]

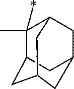 [SMILES: *C1(C)C2CC3CC(C2)CC1C3]

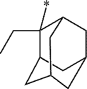 [SMILES: *C1(CC)C2CC3CC(C2)CC1C3]

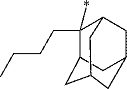 [SMILES: *C1(CCCC)C2CC3CC(C2)CC1C3]

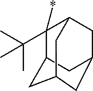 [SMILES: *C1(C(C)(C)C)C2CC3CC(C2)CC1C3]

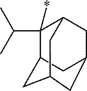 [SMILES: *C1(C(C)C)C2CC3CC(C2)CC1C3]

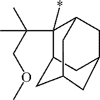 [SMILES: *C1(C(C)(C)COC)C2CC3CC(C2)CC1C3]

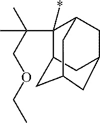 [SMILES: *C1(C(C)(C)COCC)C2CC3CC(C2)CC1C3]

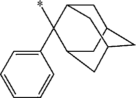 [SMILES: *C1(c2ccccc2)C2CC3CC(C2)CC1C3]

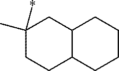 [SMILES: *C1(C)CCC2CCCCC2C1]

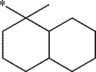 [SMILES: *C1(C)CCCC2CCCCC21]

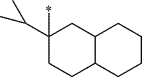 [SMILES: *C1(C(C)C)CCC2CCCCC2C1]

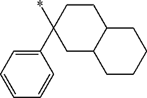 [SMILES: *C1(c2ccccc2)CCC2CCCCC2C1]

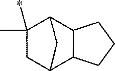 [SMILES: *C1(C)CC2CC1C1CCCC21]

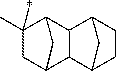 [SMILES: *C1(C)CC2CC1C1C3CCC(C3)C21]

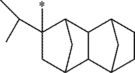 [SMILES: *C1(C(C)C)CC2CC1C1C3CCC(C3)C21]

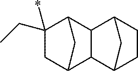 [SMILES: *C1(CC)CC2CC1C1C3CCC(C3)C21]

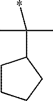 [SMILES: *C(C)(C)C1CCCC1]

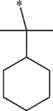 [SMILES: *C(C)(C)C1CCCCC1]

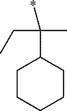 [SMILES: *C(C)(CC)C1CCCCC1]

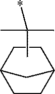

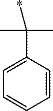 [SMILES: *C(C)(C)c1ccccc1]

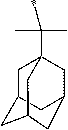 [SMILES: *C(C)(C)C12CC3CC(CC(C3)C1)C2]

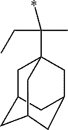 [SMILES: *C(C)(CC)C12CC3CC(CC(C3)C1)C2]

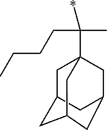 [SMILES: *C(C)(CCCC)C12CC3CC(CC(C3)C1)C2]

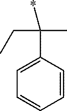 [SMILES: *C(C)(CC)c1ccccc1]

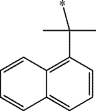 [SMILES: *C(C)(C)c1cccc2ccccc12]

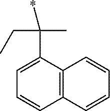 [SMILES: *C(C)(CC)c1cccc2ccccc12]

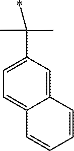 [SMILES: *C(C)(C)c1ccc2ccccc2c1]

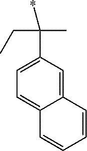 [SMILES: *C(C)(CC)c1ccc2ccccc2c1]

In the above Group 2, “*” denotes a binding site.

A vast amount of research has been conducted into an extreme ultraviolet (EUV) lithography technique incorporating an exposure process using EUV light having a very short wavelength of about 13.5 nm as an advanced technique for superseding a lithography process using a krypton fluoride (KrF) excimer laser (248 nm) and an argon fluoride (ArF) excimer laser (193 nm). An EUV lithography process may be based on a different action mechanism from the lithography process using the KrF excimer laser and the ArF excimer laser. In the EUV lithography process, in an exposed area of a photoresist film obtained from a typical photoresist composition, a protecting group of a polymer included in the photoresist film may be deprotected through a one-step deprotection reaction due to photoacid generated from a photoacid generator (PAG), and thus, the polarity of the polymer may be changed. As a result, a pattern may be formed from the photoresist film. However, in the photoresist film obtained from the typical photoresist composition, the polarity of the polymer may gradually change according to the concentration of photoacid generated from the PAG at a boundary between an exposed area and a non-exposed area. As a result, there may be a limit in improving the line edge roughness (LER) and the line width roughness (LWR) of the pattern obtained from the photoresist film. Thus, it may be difficult to achieve a high pattern fidelity.

On the other hand, a photosensitive polymer according to an example embodiment may include the first repeating unit of Formula 1. In the photosensitive polymer according to an example embodiment, the first repeating unit of Formula 1 may have a structure in which a two-step deprotection reaction sequentially occurs due to acid. After the two-step deprotection reaction, the polarity of the photosensitive polymer may be changed. Therefore, in the photoresist film obtained from the photoresist composition including the photosensitive polymer according to an example embodiment, a dissolution contrast, for a developer, between the exposed area and the non-exposed area may be maximized to improve an LER and an LWR. Thus, a high pattern fidelity may be achieved.

Without being bound by theory, the first repeating unit of Formula 1, which is included in the photosensitive polymer according to an example embodiment, may be subjected to a two-step deprotection reaction due to photoacid as shown in Reaction Scheme 1:

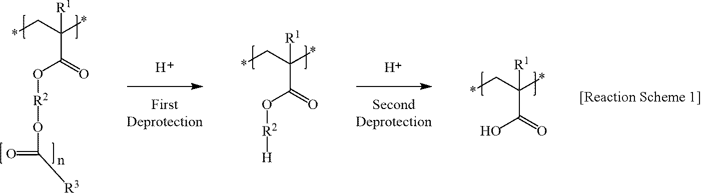

In Reaction Scheme 1, the R³ group may be deprotected through a first deprotection reaction. In this case, because an ether group (—O—) or an ester group (carboxylic group: —C(═O)—O—) has high hydrophilicity, the R³ group may be deprotected while an ether group or an ester group, which is closest to the R³ group, is connected to the R³ group. In addition, the R² group, which is relatively hydrophobic, may remain connected to the backbone of the first repeating unit. As a result, after the first deprotection reaction, the polarity of the first repeating unit may hardly change.

An intermediate product obtained after the first deprotection reaction in Reaction Scheme 1 may be subjected to a second deprotection reaction due to photoacid. The R² group may be deprotected through the second deprotection reaction. As a result, the first repeating unit may have a structure terminated with a relatively highly hydrophilic carboxyl group (-COOH). As described above, the hydrophilicity of the first repeating unit may be increased only after the second deprotection reaction, and thus, the polarity of the first repeating unit may be changed.

In a photosensitive polymer according to an example embodiment, in which the first repeating unit of Formula 1 is included, the photoresist film including the photosensitive polymer may have a reduced sensitivity to acid, and a dissolution contrast for a developer between the exposed area and the non-exposed area of the photoresist film may be maximized.

A photosensitive polymer according to an example embodiment may further include a second repeating unit that decomposes by the action of acid and generates phenolic acid or BrOnsted acid corresponding to the phenolic acid.

In an example embodiment, the second repeating unit may include a structure that is derived from hydroxystyrene or derivatives thereof. The derivatives of hydroxystyrene may include hydroxystyrenes in which a hydrogen atom at an a site is substituted with a C1 to C5 alkyl group or a C1 to C5 halogenated alkyl group, and derivatives thereof. In an example embodiment, the second repeating unit may include a structure that is derived from methoxystyrene or derivatives thereof.

In an example embodiment, the second repeating unit may have a structure of Formula 2 below:

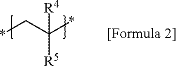

wherein, in Formula 2, R⁴ is a hydrogen atom or a methyl group, R⁵ is a C6 to C30 aryl group including at least one hydroxy group or at least one methoxy group, and * denotes a binding site.

In an example embodiment, R⁵ may include any one selected from a phenyl group, a naphthyl group, and an anthracenyl group, each of which includes at least one hydroxy group or at least one methoxy group.

In an example embodiment, in Formula 2, R⁵ may have any one selected from the structures of the following Group 3. [Group 3]

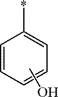

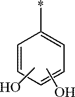

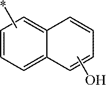

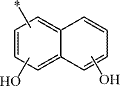

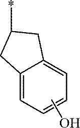

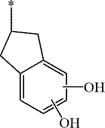

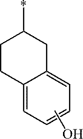

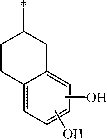

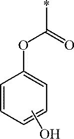

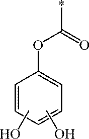

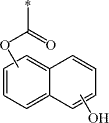

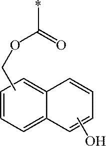

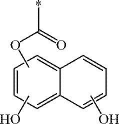

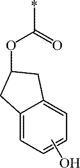

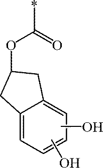

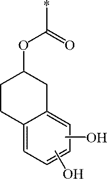

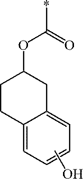

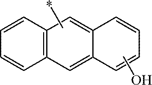

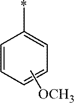

In the above Group 3, “*” denotes a binding site.

In an example embodiment, the photosensitive polymer according to an example embodiment may include a structure represented by Formula 3 below:

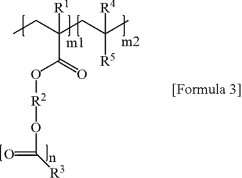

wherein, in Formula 3, each of R¹ and R⁴ is a hydrogen atom or a methyl group, R² is a substituted or unsubstituted C1 to C30 acid-labile hydrocarbylene group having a tertiary carbon atom, R³ is a substituted or unsubstituted C1 to C10 linear or branched alkyl group, a substituted or unsubstituted C3 to C30 tertiary alicyclic group, a substituted or unsubstituted C6 to C20 aryl group, a substituted or unsubstituted C2 to C20 heteroaryl group, a substituted or unsubstituted C7 to C20 arylalkyl group, or a substituted or unsubstituted C2 to C20 heteroarylalkyl group, R⁵ is a C6 to C30 aryl group including at least one hydroxy group or at least one methoxy group, n is 0 or 1, and each of m 1/(m 1+m2) and m2/(m 1+m2) is in a range of about 0.4 to about 0.6.

In an example embodiment, in Formula 3, a value of m2/(ml+m2) may be greater than a value of m 1/(m 1+m2).

In Formula 3, detailed descriptions of R², R³, and R⁵ may be the same as given above.

The photosensitive polymer represented by Formula 3 may have a weight-average molecular weight Mw of about 1,000 to about 500,000 Daltons.

A photoresist composition according to an example embodiment may include a photosensitive polymer including a first repeating unit represented by Formula 1, a PAG, and a solvent.

A detailed description of the photosensitive polymer including the first repeating unit may be the same as given above. In an example embodiment, the photosensitive polymer may further include a second repeating represented by Formula 2. In an example embodiment, the photosensitive polymer may include a structure represented by Formula 3. A detailed description of the photosensitive polymer may be the same as given above.

In an example embodiment, the photosensitive polymer may include a blend of a first polymer having the first repeating unit and a second polymer having the second repeating unit.

In an example embodiment, the photosensitive polymer may further include at least one of a third repeating unit including a (meth)acrylate-based monomer unit having a substituent including a hydroxy group (—OH) and a fourth repeating unit including a (meth)acrylate-based monomer unit having a protecting group substituted with fluorine.

In the photoresist composition, the photosensitive polymer may be included at a content of about 1% to about 25% by weight, based on the total weight of the photoresist composition.

The PAG included in the photoresist composition according to an example embodiment may generate an acid when exposed to any one selected from a krypton fluoride (KrF) excimer laser (248 nm), an argon fluoride (ArF) excimer laser (193 nm), a fluorine (F₂) excimer laser (157 nm), and an extreme ultraviolet (EUV) laser (13.5 nm). The PAG may include a material that generates a relatively strong acid having a pKa of about -20 or more and less than about 1 due to exposure.

In an example embodiment, the PAG may include a triarylsulfonium salt, a diaryliodonium salt, a sulfonate, or a mixture thereof. For example, the PAG may include triphenylsulfonium triflate, triphenylsulfonium antimonate, diphenyliodonium triflate, diphenyliodonium antimonate, methoxydiphenyliodonium triflate, di-t-butyldiphenyliodonium triflate, 2,6-dinitrobenzyl sulfonate, pyrogallol tris(alkylsulfonate), N-hydroxysuccinimide triflate, norbornene-dicarboximide-triflate, triphenylsulfonium nonaflate, diphenyliodonium nonaflate, methoxydiphenyliodonium nonaflate, di-t-butyldiphenyliodonium nonaflate, N-hydroxysuccinimide nonaflate, norbornene-dicarboximide-nonaflate, triphenylsulfonium perfluorobutanesulfonate, triphenylsulfonium perfluorooctanesulfonate (PFOS), diphenyliodonium PFOS, methoxydiphenyliodonium PFOS, di-t-butyldiphenyliodonium triflate, N-hydroxysuccinimide PFOS, or norbornene-dicarboximide PFOS, or a mixture thereof.

In the photoresist composition according to an example embodiment, the PAG may be included at a content of about 0.1% to about 5.0% by weight, based on the total weight of the photosensitive polymer.

In the photoresist composition according to an example embodiment, the solvent may include an organic solvent. In an example embodiment, the solvent may include at least one of an ether, an alcohol, a glycol ether, an aromatic hydrocarbon compound, a ketone, or an ester. For example, the solvent may be selected from ethylene glycol monomethylether, ethylene glycol monoethylether, methylcellosolve acetate, ethylcellosolve acetate, diethylene glycol monomethylether, diethylene glycol monoethylether, propylene glycol, propylene glycol monomethylether, propylene glycol monomethylether acetate, propylene glycol monoethylether, propylene glycol monoethylether acetate, propylene glycol propylether acetate, propylene glycol monobutylether, propylene glycol monobutylether acetate, toluene, xylene, methylethyl ketone, cyclopentanone, cyclohexanone, 2-hydroxypropionate ethyl, 2-hydroxy-2-methylpropionate ethyl, ethyl ethoxyacetate, ethyl hydroxyacetate, 2-hydroxy-3-methylbutanoate methyl, 3-methoxypropionate methyl, 3-methoxypropionate ethyl, 3-ethoxypropionate ethyl, 3-ethoxypropionate methyl, methyl pyruvate, ethyl pyruvate, ethyl acetate, butyl acetate, ethyl lactate, and butyl lactate. The solvents described above may be used alone or in combination of at least two kinds thereof. In an example embodiment, the amount of the solvent in the photoresist composition may be adjusted so that a solid content of the photoresist composition ranges from about 3% to about 20% by weight.

The photoresist composition according to an example embodiment may further include a basic quencher.

For example, when an acid generated from the PAG included in the photoresist composition according to an example embodiment diffuses into a non-exposed area of a photoresist film, the basic quencher may trap the acid in the non-exposed area of the photoresist film. Including the basic quencher in the photoresist composition according to an example embodiment may help prevent issues relating to diffusion of an acid, generated in an exposed area of the photoresist film, into the non-exposed area thereof, after the photoresist film obtained from the photoresist composition is exposed.

In an example embodiment, the basic quencher may include a primary aliphatic amine, a secondary aliphatic amine, a tertiary aliphatic amine, an aromatic amine, a heterocyclic amine, a nitrogen-containing compound having a carboxyl group, a nitrogen-containing compound having a sulfonyl group, a nitrogen-containing compound having a hydroxyl group, a nitrogen-containing compound having a hydroxyphenyl group, an alcoholic nitrogen-containing compound, an amide, an imide, a carbamate, or an ammonium salt. For example, the basic quencher may include triethanol amine, triethyl amine, tributyl amine, tripropyl amine, hexamethyl disilazane, aniline, N-methylaniline, N-ethylaniline, N-propylaniline, N,N-dimethylaniline, N,N-bis(hydroxyethyl)aniline, 2-methylaniline, 3-methylaniline, 4-methylaniline, ethylaniline, propylaniline, dimethylaniline, 2,6-diisopropylaniline, trimethylaniline, 2-nitroaniline, 3-nitroaniline, 4-nitroaniline, 2,4-dinitroaniline, 2,6-dinitroaniline, 3,5-dinitroaniline, or N,N-dimethyltoluidine, or a combination thereof.

In an example embodiment, the basic quencher may include a photo-decomposable base. The photo-decomposable base may include a compound that generates acid due to exposure and neutralizes the acid before exposure. The photo-decomposable base may lose ability to trap the acid when decomposed due to exposure. Accordingly, when a partial region of a photoresist film that is formed using a chemically amplified photoresist composition including the basic quencher including the photo-decomposable base is exposed, the photo-decomposable base may lose alkalinity in an exposed area of the photoresist film, while the photo-decomposable base may trap acid in a non-exposed area of the photoresist film. Thus, problems caused by diffusion of the acid generated in the exposed areas of the photoresist film into the non-exposed area of the photoresist film may be prevented.

The photo-decomposable base may include a carboxylate or sulfonate salt of a photo-decomposable cation. For example, the photo-decomposable cation may form a complex with an anion of C1 to C20 carboxylic acid. The carboxylic acid may be, for example, formic acid, acetic acid, propionic acid, tartaric acid, succinic acid, cyclohexylcarboxylic acid, benzoic acid, or salicylic acid.

In the photoresist composition according to an example embodiment, the basic quencher may be contained at a content of about 0.01% to about 5.0% by weight, based on a total weight of the photosensitive polymer, but is not limited thereto.

In the photoresist composition according to an example embodiment, the solvent may be contained at a content of the remaining percentage excluding the contents of main components including the photosensitive polymer and the PAG. In an example embodiment, the solvent may be included at a content of about 0.1% to about 99.7% by weight, based on the total weight of the photoresist composition.

In an example embodiment, the photoresist composition may further include at least one selected from a surfactant, a dispersant, or a coupling agent.

The surfactant may improve the coating uniformity and wettability of the photoresist composition. In an example embodiment, the surfactant may include a sulfuric acid ester salt, a sulfonate, a phosphate ester, a soap, an amine salt, a quaternary ammonium salt, a polyethylene glycol, an alkylphenol ethylene oxide adduct, a polyhydric alcohol, or a nitrogen-containing vinyl polymer, or a combination thereof. For example, the surfactant may include an alkylbenzene sulfonate, an alkylpyridinium salt, a polyethylene glycol, or a quaternary ammonium salt. When the photoresist composition includes the surfactant, the surfactant may be included at a content of about 0.001% to about 3% by weight, based on the total weight of the photoresist composition.

The dispersant may uniformly disperse respective components in the photoresist composition. In an example embodiment, the dispersant may include an epoxy resin, polyvinyl alcohol, polyvinyl butyral, polyvinylpyrrolidone, glucose, sodium dodecyl sulfate, sodium citrate, oleic acid, or linoleic acid, or a combination thereof. When the photoresist composition includes the dispersant, the dispersant may be contained at a content of about 0.001% to about 5% by weight, based on the total weight of the photoresist composition.

The coupling agent may increase adhesion of the photoresist composition with an underlayer film when the underlayer film is coated with the photoresist composition. In an example embodiment, the coupling agent may include a silane coupling agent. The silane coupling agent may include vinyl trimethoxysilane, vinyl triethoxysilane, vinyl trichlorosilane, vinyl tris(β-methoxyethoxy)silane, 3-methacryl oxypropyl trimethoxysilane, 3-acryl oxypropyl trimethoxysilane, p-styryl trimethoxysilane, 3-methacryl oxypropyl methyldimethoxysilane, 3-methacryl oxypropyl methyldiethoxysilane, or trimethoxy[3-(phenylamino)propyl]silane. When the photoresist composition includes the coupling agent, the coupling agent may be contained at a content of about 0.001% to about 5% by weight, based on the total weight of the photoresist composition.

In the photoresist composition according to an example embodiment, when the solvent includes only the organic solvent, the photoresist composition may further include water. In this case, water may be contained at a content of about 0.001% to about 0.1% by weight, in the photoresist composition.

As described above, a photoresist composition according to an example embodiment may include a photosensitive polymer including the first repeating unit of Formula 1. In the photosensitive polymer according to the embodiments, the first repeating unit of Formula 1 may have a structure in which a two-step deprotection reaction due to acid occurs sequentially. After the two-step deprotection reaction, the polarity of the photosensitive polymer may be changed. As a result, in the photoresist film obtained from the photoresist composition according to the embodiments, a dissolution contrast for a developer between the exposed area and the non-exposed area may be maximized to improve an LER and an LWR. Thus, a high pattern fidelity may be achieved. Therefore, when a photolithography process for manufacturing an IC device is performed using the photoresist composition according to the embodiment, a sufficient dissolution contrast for a developer between the exposed area and the non-exposed area of the photoresist film may be ensured to improve resolution. Accordingly, by manufacturing the IC device by using the photoresist composition according to an example embodiment, a dimensional precision of a pattern required for the IC device may be improved, and the productivity of a process of manufacturing an IC device may be increased.

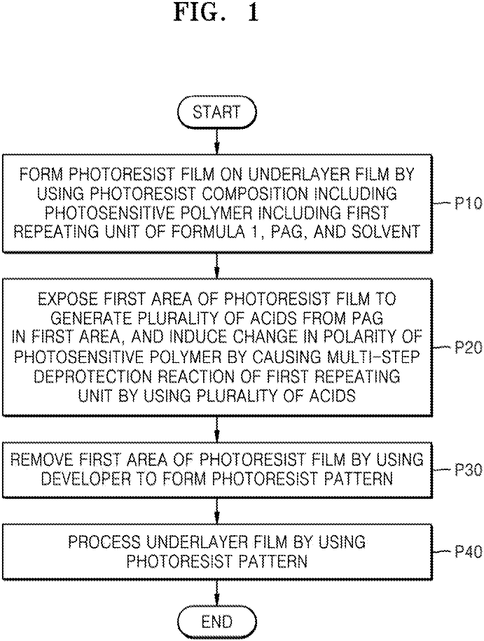

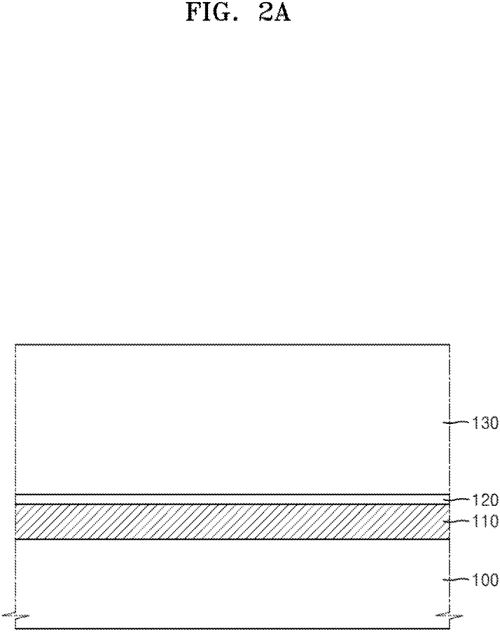

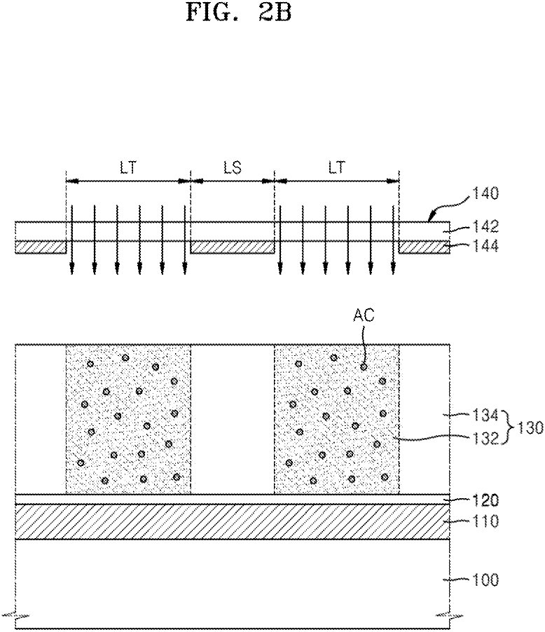

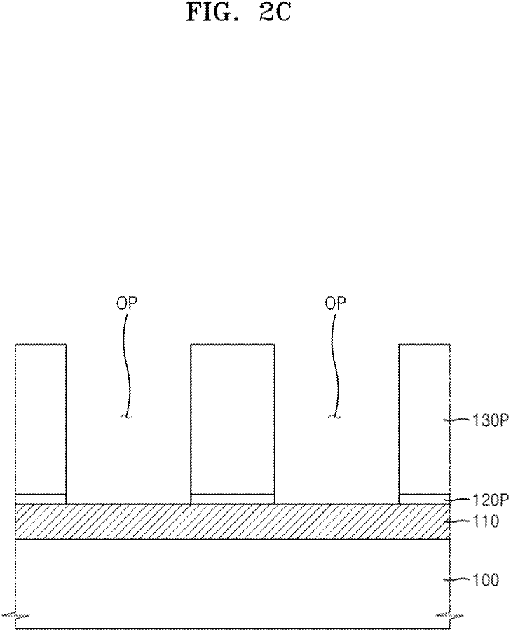

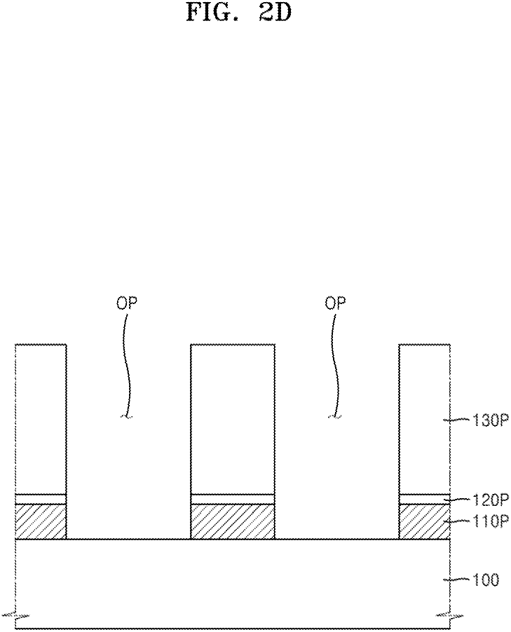

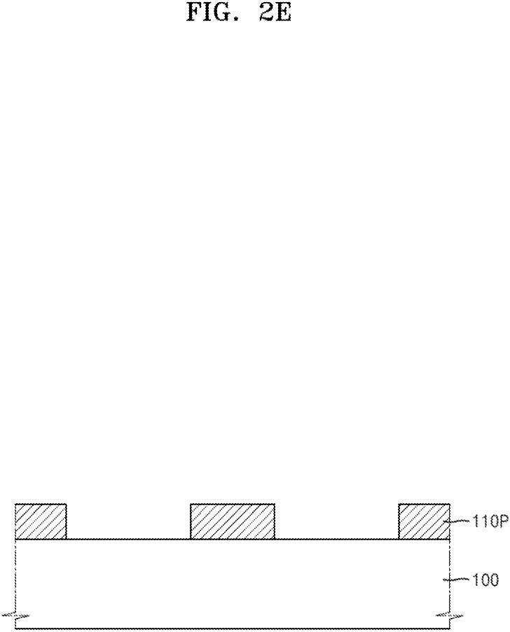

FIG. 1 is a flowchart of a method of manufacturing an integrated circuit (IC) device, according to an example embodiment. FIGS. 2A to 2E are cross-sectional views of a process sequence of a method of manufacturing an IC device, according to an example embodiment.

Referring to FIGS. 1 and 2A, in process P10 of FIG. 1, a photoresist film 130 may be formed on an underlayer film.

The underlayer film may include a substrate 100 and a feature layer 110 formed on the substrate 100.

The substrate 100 may include a semiconductor substrate. For example, the substrate 100 may include an elemental semiconductor material (e.g., silicon (Si) or germanium (Ge)) or a compound semiconductor material (e.g., silicon germanium (SiGe), silicon carbide (SiC), gallium arsenide (GaAs), indium arsenide (InAs), or indium phosphide (InP)).

The feature layer 110 may include an insulating film, a conductive film, or a semiconductor film. For example, the feature layer 110 may include a metal, an alloy, a metal carbide, a metal nitride, a metal oxynitride, a metal oxycarbide, a semiconductor, polysilicon, oxide, nitride, oxynitride, or a combination thereof.

In an example embodiment, as shown in FIG. 2A, before the photoresist film 130 is formed on the feature layer 110, a developable bottom anti-reflective coating (DBARC) film 120 may be formed on the feature layer 110. In this case, the photoresist film 130 may be formed on the DBARC film 120.

The DBARC film 120 may control diffuse reflection of light from a light source used during an exposure process for manufacturing an IC device or absorb reflected light from the feature layer 110 located thereunder. In an example embodiment, the DBARC film 120 may include an organic anti-reflective coating (ARC) material for a KrF excimer laser, an ArF excimer laser, or any other light source. In an example embodiment, the DBARC film 120 may include an organic component having a light-absorbing structure. The light-absorbing structure may include, for example, at least one benzene ring or a hydrocarbon compound in which benzene rings are fused. The DBARC film 120 may be formed to a thickness of about 20 nm to about 100 nm. In an example embodiment, the DBARC film 120 may be omitted.

To form the photoresist film 130, a photoresist composition including a photosensitive polymer according to an example embodiment may be used. In an example embodiment, the photoresist composition may include a photosensitive polymer including a first repeating unit represented by Formula 1, a PAG, and a solvent. In an example embodiment, the photoresist composition may further include a basic quencher. Detailed descriptions of the photosensitive polymer and the photoresist composition may be the same as given above.

To form the photoresist film 130, the DBARC film 120 may be coated with a photoresist composition according to an example embodiment, and the photoresist composition may be then annealed. The coating process may be performed using, for example, a spin coating process, a spray coating process, and a deep coating process. The process of annealing the photoresist composition may be performed at a temperature of about 80° C. to about 300° C. for about 10 seconds to about 100 seconds. A thickness of the photoresist film 130 may be several times to several hundred times a thickness of the DBARC film 120. The photoresist film 130 may be formed to a thickness of about 100 nm to about 6 µm.

Referring to FIGS. 1 and 2B, in process P20, a first area 132, which is a portion of the photoresist film 130, may be exposed, and thus, a plurality of acids AC may be generated from the PAG in the first area 132 of the photoresist film 130. A multi-step deprotection reaction of the first repeating unit included in the photosensitive polymer may be caused by using the plurality of acids AC, and thus, a change in the polarity of the photosensitive polymer may be induced.

In an example embodiment, to expose the first area 132 of the photoresist film 130, a photomask 140 having a plurality of light-shielding areas LS and a plurality of light-transmitting areas LT may be arranged at a predetermined position on the photoresist film 130, and the first area 132 of the photoresist film 130 may be exposed through the plurality of light-transmitting areas LT of the photomask 140. The first area 132 of the photoresist film 130 may be exposed using a KrF excimer laser (248 nm), an ArF excimer laser (193 nm), an F₂ excimer laser (157 nm), or an EUV laser (13.5 nm).

The photomask 140 may include a transparent substrate 142 and a plurality of light-shielding patterns 144 formed in the plurality of light-shielding areas LS on the transparent substrate 142. The transparent substrate 142 may include quartz. The plurality of light-shielding patterns 144 may include chromium (Cr). The plurality of light-transmitting areas LT may be defined by the plurality of light-shielding patterns 144.

In an example embodiment, an annealing process may be performed to diffuse the plurality of acids AC in the first area 132 of the photoresist film 130. For example, the resultant structure, which is obtained after the first area 132 of the photoresist film 130 is exposed in process P20 of FIG. 1, may be annealed at a temperature of about 50° C. to about 150° C. Thus, at least some of the plurality of acids AC may be diffused in the first area 132 of the photoresist film 130 so that the plurality of acids AC may be relatively uniformly distributed in the first area 132 of the photoresist film 130. The annealing process may be performed for about 10 seconds to about 100 seconds. In an example embodiment, the annealing process may be performed at a temperature of about 100° C. for about 60 seconds.

In an example embodiment, an additional annealing process may not be performed to diffuse the plurality of acids AC in the first area 132 of the photoresist film 130. In this case, in process P20 of FIG. 1, during the exposing of the first area 132 of the photoresist film 130, the plurality of acids AC may be diffused in the first area 132 of the photoresist film 130 without the additional annealing process.

By diffusing the plurality of acids AC in the first area 132 of the photoresist film 130, as shown in Reaction Scheme 1, the first repeating unit of Formula 1, which is included in the photosensitive polymer that forms the photoresist film 130, may be subjected to a two-step deprotection reaction due to photoacid in the first area 132 of the photoresist film 130. A detailed description of the two-step deprotection reaction may be the same as given with reference to Reaction Scheme 1. After undergoing a second deprotection reaction according to Reaction Scheme 1, the photosensitive polymer may be changed in polarity to increase hydrophilicity thereof, and the first area 132 of the photoresist film 130 may be changed to a state in which the first area 132 of the photoresist film 130 may be easily dissolved in an alkali developer.

Because the energy intensity of light irradiated to the first area 132, which is an exposed area of the photoresist film 130, follows a Gaussian distribution, the energy density of a central portion of a beam spot irradiated with light may be high, and the energy density of the beam spot may be reduced toward a peripheral region of the beam spot. A second area 134, which is a non-exposed area of the photoresist film 130, may have an edge portion adjacent to the first area 132. The edge portion of the second area 134 may be irradiated with light from the peripheral region of the beam spot, which has a relatively low energy density. As described above, even when light having a relatively low energy density is irradiated to a partial region adjacent to the first area 132, of the second area 134 that is the non-exposed area of the photoresist film 130, the first repeating unit of Formula 1, which is included in the photosensitive polymer that forms the photoresist film 130, may be likely to undergo a first deprotection reaction of Reaction Scheme 1 due to photoacid, but it may be difficult to proceed to the second deprotection reaction. Accordingly, in the second area 134 of the photoresist film 130, it may be difficult to change the polarity of the first repeating unit of Formula 1, which is included in the photosensitive polymer that forms the photoresist film 130. As a result, the sensitivity of the photoresist film 130 to acid may be reduced, and a dissolution contrast for a developer between the first area 132, which is the exposed area of the photoresist film 130, and the second area 134, which is the non-exposed area of the photoresist film 130, may be maximized.

When the basic quencher is included in the photoresist film 130, the basic quencher included in the photoresist film 130 in the second area 134, which is a non-exposed area, may act as a quenching base to neutralize acids that have been undesirably diffused from the first area 132 into the second area 134. Accordingly, it may be advantageous to maximize a dissolution contrast for a developer between the first area 132, which is the exposed area of the photoresist film 130, and the second area 134, which is the non-exposed area of the photoresist film 130.

Referring to FIGS. 1 and 2C, in process P30, the photoresist film 130 may be developed by using a developer to remove the first area 132 from the photoresist film 130.

In an example embodiment, an alkali developer may be used to develop the photoresist film 130. The alkali developer may include 2.38% by weight of a tetramethylammonium hydroxide (TMAH) solution.

As a result of the developing, a photoresist pattern 130P including the second area 134 of the photoresist film 130, which is the non-exposed area, may be formed.

The photoresist pattern 130P may include a plurality of openings OP. After the photoresist pattern 130P is formed, a portion of the DBARC film 120, which is exposed through the plurality of openings OP, may be removed to form a DBARC pattern 120P.

In the resultant structure of FIG. 2B, after undergoing the second deprotection reaction, the photosensitive polymer may remain highly hydrophilic in the first area 132 of the photoresist film 130. Accordingly, the solubility of the first area 132 in the developer may be increased during the development of the photoresist film 130 with the developer in the process described with reference to FIG. 2C, and thus, the first area 132 may be removed cleanly. Accordingly, the photoresist pattern 130P may obtain a vertical sidewall profile. As described above, by improving a profile of the photoresist pattern 130P, when the feature layer 110 is processed using the photoresist pattern 130P, a critical dimension (CD) of an intended processing region may be precisely controlled in the feature layer 110.

Referring to FIGS. 1 and 2D, in process P40, the underlayer film may be processed using the photoresist pattern 130P in the resultant structure of FIG. 2C.

To process the underlayer film, various processes, such as a process of etching the feature layer 110 exposed by the openings OP of the photoresist pattern 130P, a process of implanting impurity ions into the feature layer 110, a process of forming an additional film on the feature layer 110 through the openings OP, and a process of modifying portions of the feature layer 110 through the openings OP, may be performed. FIG. 2D illustrates a process of forming a feature pattern 110P by etching the feature layer 110, which is exposed by the openings OP, as an example of processing the underlayer film.

In an example embodiment, the forming of the feature layer 110 may be omitted from the process described with reference to FIG. 2A. In this case, the substrate 100 may be processed using the photoresist pattern 130P instead of the process described with reference to the process P40 of FIG. 1 and FIG. 2D. For example, various processes, such as a process of etching a portion of the substrate 100 using the photoresist pattern 130P, a process of implanting impurity ions into a partial region of the substrate 100, a process of forming an additional film on the substrate 100 through the openings OP, and a process of modifying portions of the substrate 100 through the openings OP, may be performed.

Referring to FIG. 2E, the photoresist pattern 130P and the DBARC pattern 120P, which remain on the feature pattern 110P, may be removed from the resultant structure of FIG. 2D. The photoresist pattern 130P and the DBARC pattern 120P may be removed using an ashing process and a strip process.

In the method of manufacturing the IC device described with reference to FIGS. 1 and 2A to 2E, a difference in solubility in the developer between the exposed area and the non-exposed area of the photoresist film 130 obtained using the photoresist composition according to an example embodiment may be increased. Thus, an LER and an LWR may be reduced in the photoresist pattern 130P obtained from the photoresist film 130 to provide a high pattern fidelity. Accordingly, when a subsequent process is performed on the feature layer 110 and/or the substrate 100 using the photoresist pattern 130P, a dimensional precision may be improved by precisely controlling CDs of processing regions or patterns to be formed in the feature layer 110 and/or the substrate 100. In addition, a CD distribution of patterns to be formed on the substrate 100 may be uniformly controlled, and the productivity of a process of manufacturing an IC device may be increased.

### Synthesis Example

Synthesis of monomer

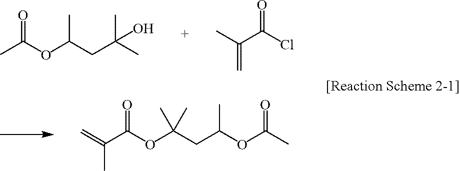

A synthesis process of Reaction Scheme 2-1 was performed. More specifically, 2.1 g (20 mmol) of methacryloyl chloride was put in a 250-mL flask and dissolved in 50 mL of a tetrahydrofuran (THF) solvent, which was dried by nitrogen (N₂) bubbling to prepare a solution. 2.4 g (24 mmol) of trimethylamine was slowly added to the solution at a rate of about 10 mL/min while being stirred. Thereafter, a solution prepared by separately dissolving 3.2 g (20 mmol) of 4-acetoxy-2-methylpentan-2-ol in 10 mL of THF was slowly added to the obtained product at a rate of about 10 mL/min, and then reacted for about 12 hours. After the reaction was completed, the solvent was completely evaporated, and the obtained residue was dissolved in 20 mL of ethyl acetate. An organic layer was collected using a distilled water-ethyl acetate separatory funnel. Afterwards, the organic layer was dried with dehydrated magnesium sulfate, filtered, and the solvent was removed by vacuum. The obtained product was separated and purified by silica gel chromatography to obtain 3.6 g of the product of Reaction Scheme 2-1 (2-propenoic acid, 2-methyl-, 3-(acetyloxy)-1,1-dimethylbutyl ester) (yield: 79 %).

¹H NMR (300 MHz, DMSO-d⁶) 8 : 1.35-1.45 (9H, (m)) 1.78 (2H, (d)) 1.87 (3H, (s)) 2.05 (3H, (s)), 4.8 (1H, (m)) 5.5 (1H, (d) 6 (1H, (d))

Synthesis of polymer

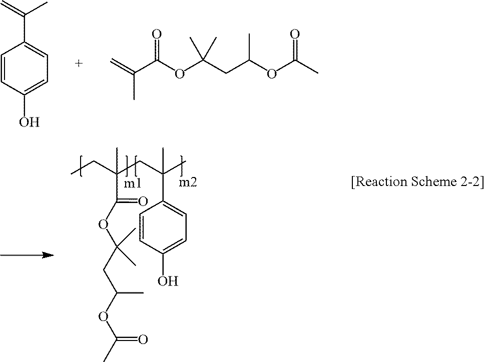

A synthesis process of Reaction Scheme 2-2 was performed. More specifically, 2.28 g (10 mmol) of the product of Reaction Scheme 2-1, 1.34 g (10 mmol) of 4-hydroxyl styrene, and 0.16 g of azobisisobutyronitrile (AIBN) were dissolved in 100 mL of a dried THF solvent in a flask, and oxygen and water were then removed from the flash by N₂ bubbling for at least 4 hours. Thereafter, the obtained product was reacted by stirring at a temperature of about 70° C. for about 12 hours. After the completion of the reaction, the flask was cooled to room temperature and exposed to the air to quench the remaining reactants. The obtained polymer was precipitated under THF/hexane conditions, and the solvent was evaporated to obtain a primary product. The primary product was stirred in NaOMe/methanol for about 6 hours and acidified with acetic acid. Thereafter, the obtained product was precipitated by using distilled water, and the solvent was then evaporated to obtain 2.3 g of a final product (yield: 65 %).

¹H NMR (300 MHz, DMSO-d⁶) 8 : 1.35-1.45 (9H, (m)) 1.6 (9H, (d)) 1.78 (2H, (d)) 1.87 (3H, (s)) 2.05 (3H, (s)), 4.8 (1H, (m)) 5.5 (1H, (d) 6 (1H, (d)).

By way of summation and review, in a photolithography process for manufacturing an IC device, it is desirable to improve dissolution contrast between an exposed area and a non-exposed area of a photoresist film, for a developer.

As described above, example embodiments may provide a photosensitive polymer that may improve a dissolution contrast for a developer between an exposed area and a non-exposed area of a photoresist film.

Example embodiments may also provide a photoresist composition that may improve a dissolution contrast for a developer between an exposed area and a non-exposed area of a photoresist film during a photolithography process for manufacturing an integrated circuit (IC) device.

Example embodiments may also provide a method of manufacturing an IC device, which may improve a dissolution contrast for a developer between an exposed area and a non-exposed area of a photoresist film during a photolithography process to improve the dimensional precision of a pattern to be formed.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A photosensitive polymer, comprising a first repeating unit represented by Formula 1: 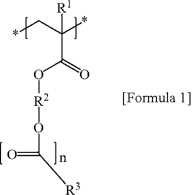
wherein, in Formula 1,
R¹ is a hydrogen atom or a methyl group,
R² is a substituted or unsubstituted C1 to C30 acid-labile hydrocarbylene group having a tertiary carbon atom,
R³ is a substituted or unsubstituted C1 to C10 linear or branched alkyl group, a substituted or unsubstituted C3 to C30 tertiary alicyclic group, a substituted or unsubstituted C6 to C20 aryl group, a substituted or unsubstituted C2 to C20 heteroaryl group, a substituted or unsubstituted C7 to C20 arylalkyl group, or a substituted or unsubstituted C2 to C20 heteroarylalkyl group,
n is 0 or 1, and
* denotes a binding site.

2. The photosensitive polymer as claimed in claim 1, wherein, in Formula 1, R² is a divalent saturated or unsaturated aliphatic hydrocarbon group.

3. The photosensitive polymer as claimed in claim 1, wherein, in Formula 1, R² is a divalent saturated or unsaturated aromatic hydrocarbon group.

4. The photosensitive polymer as claimed in claim 1, wherein, in Formula 1, R² is a C1 to C10 linear or branched alkylene group.

5. The photosensitive polymer as claimed in claim 1, further comprising a second repeating unit represented by Formula 2: 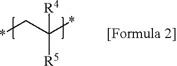
wherein, in Formula 2,
R⁴ is a hydrogen atom or a methyl group,
R⁵ is a C6 to C30 aryl group including at least one hydroxy group or at least one methoxy group, and
* denotes a binding site.

6. The photosensitive polymer as claimed in claim 1, wherein the photosensitive polymer includes a structure represented by Formula 3: 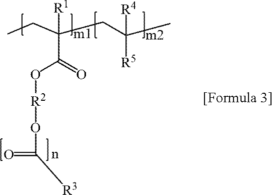
wherein, in Formula 3,
each of R¹, R², R³, and n is the same as defined in Formula 1,
R⁴ is a hydrogen atom or a methyl group,
R⁵ is a C6 to C30 aryl group including at least one hydroxy group or at least one methoxy group,
m1/(m1+m2) is in a range of 0.4 to 0.6, and
m2/(m1+m2) is in a range of 0.4 to 0.6.

7. A photoresist composition, comprising:
a photosensitive polymer including a first repeating unit represented by Formula 1;
a photoacid generator; and
a solvent, 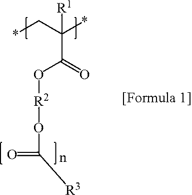
wherein, in Formula 1,
R¹ is a hydrogen atom or a methyl group,
R² is a substituted or unsubstituted C1 to C30 acid-labile hydrocarbylene group having a tertiary carbon atom,
R³ is a substituted or unsubstituted C1 to C10 linear or branched alkyl group, a substituted or unsubstituted C3 to C30 tertiary alicyclic group, a substituted or unsubstituted C6 to C20 aryl group, a substituted or unsubstituted C2 to C20 heteroaryl group, a substituted or unsubstituted C7 to C20 arylalkyl group, or a substituted or unsubstituted C2 to C20 heteroarylalkyl group,
n is 0 or 1, and
* denotes a binding site.

8. The photoresist composition as claimed in claim 7, wherein, in Formula 1, R² is a divalent saturated or unsaturated aliphatic hydrocarbon group.

9. The photoresist composition as claimed in claim 7, wherein, in Formula 1, R² is a divalent saturated or unsaturated aromatic hydrocarbon group.

10. The photoresist composition as claimed in claim 7, wherein, in Formula 1, R² includes a C1 to C10 linear or branched alkylene group.

11. The photoresist composition as claimed in claim 7, wherein the photosensitive polymer further includes a second repeating unit represented by Formula 2: 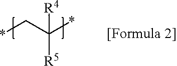
wherein, in Formula 2,
R⁴ is a hydrogen atom or a methyl group,
R⁵ is a C6 to C30 aryl group including at least one hydroxy group or at least one methoxy group, and
* denotes a binding site.

12. The photoresist composition as claimed in claim 7, wherein the photosensitive polymer includes a structure represented by Formula 3: 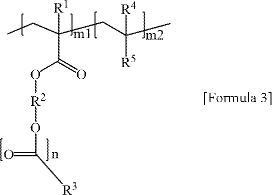
wherein, in Formula 3,
each of R¹, R², R³ and n is the same as defined in Formula 1,
R⁴ is a hydrogen atom or a methyl group,
R⁵ is a C6 to C30 aryl group including at least one hydroxy group or at least one methoxy group, and
m1/(m1+m2) is in a range of 0.4 to 0.6, and
m2/(m1+m2) is in a range of 0.4 to 0.6.

13. The photoresist composition as claimed in claim 7, further comprising a basic quencher.

14. A method of manufacturing an integrated circuit device, the method comprising:
forming a photoresist film on an underlayer film using a photoresist composition that includes a photoacid generator (PAG), a solvent, and a photosensitive polymer including a first repeating unit represented by Formula 1;
exposing a first area of the photoresist film, the first area being a portion of the photoresist film, to generate a plurality of acids from the PAG in the first area, and causing a multi-step deprotection reaction of the first repeating unit by using the plurality of acids to induce a change in polarity of the photosensitive polymer;
removing the exposed first area of the photoresist film by using a developer, to thereby form a photoresist pattern including a non-exposed area of the photoresist film; and
processing the underlayer film by using the photoresist pattern, 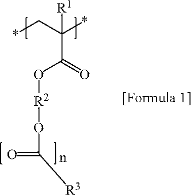
wherein, in Formula 1,
R¹ is a hydrogen atom or a methyl group,
R² is a substituted or unsubstituted C1 to C30 acid-labile hydrocarbylene group having a tertiary carbon atom,
R³ is a substituted or unsubstituted C1 to C10 linear or branched alkyl group, a substituted or unsubstituted C3 to C30 tertiary alicyclic group, a substituted or unsubstituted C6 to C20 aryl group, a substituted or unsubstituted C2 to C20 heteroaryl group, a substituted or unsubstituted C7 to C20 arylalkyl group, or a substituted or unsubstituted C2 to C20 heteroarylalkyl group,
n is 0 or 1, and
* denotes a binding site.

15. The method as claimed in claim 14, wherein, in Formula 1, R² is a divalent saturated or unsaturated aliphatic hydrocarbon group.

16. The method as claimed in claim 14, wherein, in Formula 1, R² is a divalent saturated or unsaturated aromatic hydrocarbon group.

17. The method as claimed in claim 14, wherein, in Formula 1, R² includes a C1 to C10 linear or branched alkylene group.

18. The method as claimed in claim 14, wherein, in the forming of the photoresist film, the photosensitive polymer further includes a second repeating unit represented by Formula 2: 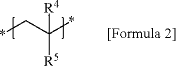
wherein, in Formula 1, R⁴ is a hydrogen atom or a methyl group, R⁵ is a C6 to C30 aryl group including at least one hydroxy group or at least one methoxy group, and * denotes a binding site.

19. The method as claimed in claim 14, wherein, in the forming of the photoresist film, the photosensitive polymer includes a structure represented by Formula 3: 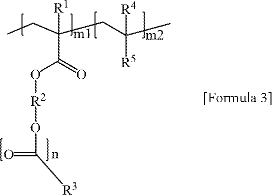
wherein, in Formula 3, each of R¹, R², R³, and n is the same as defined in claim 1, R⁴ is a hydrogen atom or a methyl group, R⁵ is a C6 to C30 aryl group including at least one hydroxy group or at least one methoxy group, and each of m1/(m1+m2) and m2/(ml+m2) is in a range of 0.4 to 0.6.

20. The method as claimed in claim 14, wherein, in the forming of the photoresist film, the photoresist composition further includes a basic quencher.
